(19) United States
(12) Patent Application Publication
(10) Pub. No.: US 2024/0196685 A1
(43) Pub. Date: Jun. 13, 2024

(54) HYBRID EMISSIVE DISPLAYS

(71) Applicant: Meta Platforms Technologies, LLC, Menlo Park, CA (US)

(72) Inventor: Yun WANG, Bellevue, WA (US)

(73) Assignee: Meta Platforms Technologies, LLC, Menlo Park, CA (US)

(21) Appl. No.: 18/528,188

(22) Filed: Dec. 4, 2023

Related U.S. Application Data
(60) Provisional application No. 63/431,534, filed on Dec. 9, 2022.

(51) Int. Cl. H10K 59/35; H01L 25/075; H01L 33/62; H10K 59/12; H10K 59/131

(52) U.S. Cl. CPC H10K 59/35; H01L 25/0753; H01L 33/62; H10K 59/1201; H10K 59/131; H01L 2933/0066

(57) ABSTRACT

According to examples, a hybrid emissive display may include a first μLED subpixel, a second μOLED subpixel, and a third μOLED or μLED subpixel. The hybrid emissive display may also include at least one digital driving component to digitally drive the first μLED subpixel, the second μOLED subpixel, and the third μOLED or μLED subpixel. For instance, the subpixels may be driven through pulse width modulation. In this regard, the μLED subpixels and the μOLED subpixels in a hybrid emissive display may be driven through at least one digital driving component that may be provided in a common backplane, which may be a CMOS backplane. As a result, for instance, hybrid emissive displays may be fabricated to include blue μLEDs and red μOLEDs.

### TECHNICAL FIELD

This patent application relates generally to emissive displays and more particularly, to hybrid emissive displays having micro organic light emitting diodes (μLEDs) and micro organic (μOLEDs).

### BACKGROUND

With recent advances in technology, prevalence and proliferation of content creation and delivery have increased greatly in recent years. In particular, interactive content such as virtual reality (VR) content, augmented reality (AR) content, mixed reality (MR) content, and content within and associated with a real and/or virtual environment (e.g., a “metaverse”) has become appealing to consumers.

Wearable display devices, such as a wearable eyewear, wearable headsets, head-mountable devices, and smartglasses, have gained in popularity as forms of wearable systems. In some examples, such as when the wearable display devices are head-mountable devices or smartglasses, the wearable display devices may employ display devices to output images to users of the wearable display devices. The display devices may include, in some instances, light emitting diodes (LEDS) or micro LEDs (LEDS), while in some other instances, the display devices may include organic LEDs (OLEDs) or micro OLEDs (μOLEDs).

### BRIEF DESCRIPTION OF DRAWINGS

Features of the present disclosure are illustrated by way of example and not limited in the following figures, in which like numerals indicate like elements. One skilled in the art will readily recognize from the following that alternative examples of the structures and methods illustrated in the figures can be employed without departing from the principles described herein.

FIG. 1A illustrates a block diagram of a conventional display system that operates under an analog driving technique.

FIG. 1B illustrates a diagram of scan and emission times for the rows of pixels in the conventional display system illustrated in FIG. 1A.

FIG. 2 illustrates a block diagram of a hybrid emissive display that may employ a digital driving technique, according to an example.

FIG. 3 illustrates a block diagram of a system environment that includes a computing device with a hybrid emissive display, according to an example.

FIG. 4 illustrates a diagram of various display devices in which the hybrid emissive display depicted in FIG. 3 may be implemented, according to examples.

FIG. 5 is a block diagram of a hybrid emissive display, according to an example.

FIGS. 6A-6D, respectively, illustrate cross-sectional front views of a portion of a hybrid emissive display, according to examples.

FIG. 7A illustrates a schematic diagram of digital driving components for a pixel having both μLED and μOLED subpixels, according to an example.

FIG. 7B illustrates a schematic diagram of a memory in a subpixel shown in FIG. 7A, according to an example.

FIG. 7C illustrates diagrams of operations of a matrix of subpixels that include memories, according to an example.

FIGS. 7D-7F, respectively, illustrate schematic diagrams of digital driving components for a pixel having both μLED and μOLED subpixels, according to examples.

FIGS. 8A-8F, collectively, illustrate operations in a method of fabricating a hybrid emissive display, according to an example.

FIGS. 9A-9C, collectively, illustrate operations in a method of fabricating a hybrid emissive display, according to an example.

### DETAILED DESCRIPTION

For simplicity and illustrative purposes, the present application is described by referring mainly to examples thereof. In the following description, numerous specific details are set forth in order to provide a thorough understanding of the present application. It will be readily apparent, however, that the present application may be practiced without limitation to these specific details. In other instances, some methods and structures readily understood by one of ordinary skill in the art have not been described in detail so as not to unnecessarily obscure the present application. As used herein, the terms “a” and “an” are intended to denote at least one of a particular element, the term “includes” means includes but not limited to, the term “including” means including but not limited to, and the term “based on” means based at least in part on.

Organic light emitting diodes (OLEDs) or micro organic light emitting diodes (μOLEDs) are currently used in many direct emission display devices, such as television screens, computer monitors, smartphones, virtual reality devices, smart watches, etc. Particularly, in OLED (and μOLED) displays, an emissive electroluminescent layer is a film of organic compound that emits light in response to an electric current. To provide the emissive electroluminescent layer with the electric current, the emissive electroluminescent layer is typically placed between two electrodes, at least one of which is transparent.

OLED displays used in smartphones, watches, or TVs are typically driven by thin film transistors (TFTs) fabricated on a glass or flexible substrate. OLED displays used in virtual reality (VR) headsets often use complementary metal-oxide semiconductor (CMOS) backplanes. OLED displays that use CMOS backplanes have a substantially smaller pixel pitch and are called μOLED displays.

OLED (and OLED) displays may have some weaknesses, such as low internal quantum efficiency and poor lifetime of blue light emitting μOLED devices. For instance, blue μOLEDs often have a quantum efficiency of about 5-10% and a lifetime of a few thousand hours before the efficiency of the blue μOLEDs drops to a point that the light emission is significantly lower than that of the red and green μOLEDs. In contrast, inorganic blue micro light emitting diodes (μLEDs) that use gallium nitride (GaN) often have quantum efficiencies that are around 40-45% and have significantly longer lifetimes than the blue μOLEDs.

Additionally, some types of μLEDs may suffer from some weaknesses. For instance, red light emitting μLEDs may have significant surface recombination that causes an efficiency drop at high current density, which may worsen in smaller devices. Red μLEDs also often use aluminum gallium indium phosphate (AlGaInP) on a gallium arsenide (GaAs) substrate, which may not be integrated into the same substrate as blue and green GaN-based μLEDs. In contrast, red μOLEDs often have quantum efficiencies that are around 20-25% and have significant lifetimes.

In many consumer displays, an analog driving method is employed to drive μLEDs and μOLEDs. Analog driving methods control the amount of light emitted by the μLEDs or OLEDs with different intensities for a given time. On the other hand, digital driving methods control the amount of light emitted with different time lengths, while the light amplitude is fixed. Analog driving methods have been dominant due to slow speeds and nonuniformity of thin film transistor (TFT) backplanes.

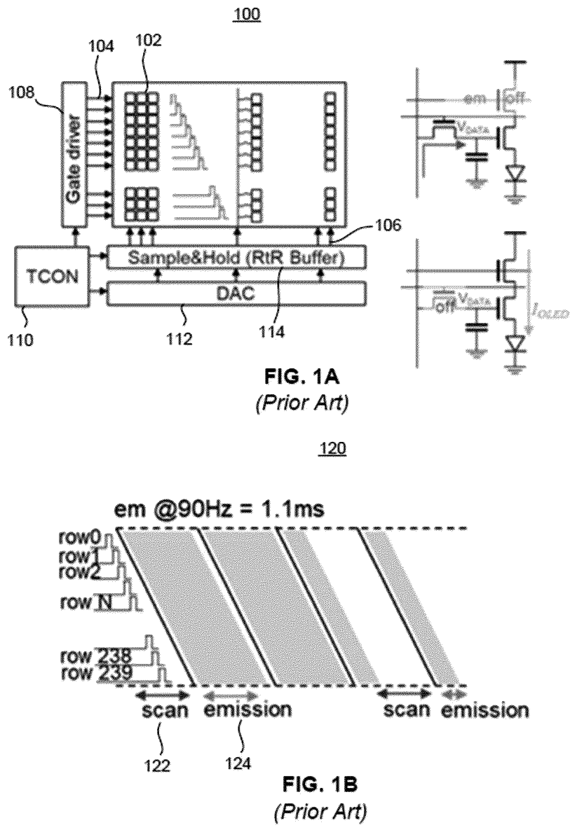

FIG. 1A illustrates a block diagram of a conventional display system 100 that operates under an analog driving method. As shown in FIG. 1A, the pixels 102 share horizontal lines 104 and vertical lines 106. In operation, an incoming digital video signal will go through a timing control (TCON) 110 and is distributed in rows and columns. The column signal is a data signal and is converted to an analog data voltage first by a digital-to-analog converter (DAC). The analog data voltage is sampled and held for a while until each of the pixels 102 reads the analog data voltage.

FIG. 1B illustrates a diagram 120 of scan 122 and emission 124 times for the rows of pixels 102 in the display system 100 illustrated in FIG. 1A. The time of the scan 122 is composed of reset time, in-pixel Vth compensation time, and data charging time. The scan time for one row may be determined by the frame rate and resolution. For a 3K panel at a 90 Hz frame rate, one-row time is 3700 ns. For a 4K panel at a 90 Hz frame rate, one-row time is 2800 ns. The charging time ranges from 500 ns to 1000 ns.

The converted analog video data is transmitted to each column line 106. In some instances, power and speed issues may occur here. In order to operate properly, the DAC 112 may be required to convert thousands of data for one-row time. Hence, the DAC 112 may need a large area, large power consumption, and high cost. Additionally, the charging time may be another issue due to the parasitic resistance and capacitance along with the data line, the buffer charge and discharge all over the line, as well as the storage capacitor in a pixel. Moreover, a real-time raytracing (RtR) buffer 114 may need to deliver exactly the same analog voltage to a storage capacitor through the column line 106. These thousands of high-speed analog buffers may cause issues of area, power, and cost.

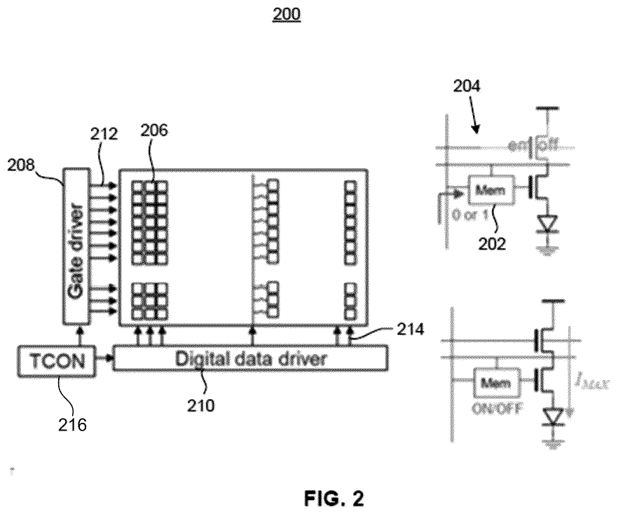

Disclosed herein are hybrid emissive displays that may include pixels including both μLED and OLED subpixels. Additionally, digital driving components may drive the hybrid emissive displays using digital data (or digital voltage). As a result, the DAC 112 as well as the RtR buffer 114 illustrated in FIG. 1A may not be used to drive the μLED and μOLED subpixels in the pixels. Instead, as shown in FIG. 2, the hybrid emissive displays 200 may employ a digital driving technique and may include a memory 202 in each of the subpixels 204 of the pixels 206. The hybrid emissive displays 200 may also include a gate driver 208 and a digital data driver 210 to digitally drive the μLED and μOLED subpixels 204 through row lines 212 and column lines 214.

In operation, an incoming digital video signal may go through a TCON 216, which may distribute the digital video signal in the row lines 212 and the column lines 214. The gate driver 208 and the digital data driver 210 may utilize pulse width modulation (PWM) to digitally drive the μOLED subpixels 204 and the μLED subpixels 204. As a result, gray levels, e.g., illumination levels, of the μOLED subpixels 204 and the μLED subpixels 204 may be controlled by the duration of the applied current as opposed to an amplitude of the applied current. In other words, the illumination levels of the μOLED subpixels 204 and the μLED subpixels 204 may be driven digitally.

Also disclosed herein are methods of fabricating hybrid emissive displays. In the methods, a prefabricated μLED subpixel may be placed and bonded to a μLED bottom electrode formed on a CMOS backplane. Following the placement and bonding of the μLED subpixel, at least one μOLED subpixel may be fabricated on the CMOS backplane. By fabricating the μOLED subpixel(s) following the placement and bonding of the μLED subpixel, the μOLED subpixel(s) may not be detrimentally affected by the increased temperatures used in bonding the μLED subpixel to the μLED bottom electrode.

Through implementation of the features of the present disclosure, both the μOLED subpixels 204 and the μLED subpixels 204 may be fabricated on the same CMOS backplane and may be driven using the same PWM driving theme. For instance, hybrid emissive displays disclosed herein may include blue light emitting μLEDs, red light emitting μOLEDs, and green light emitting μOLEDs or μLEDs on a CMOS backplane. In this regard, the hybrid emissive displays may avoid the deficiencies associated with blue light emitting μLEDs and red light emitting μOLEDs. Instead, the hybrid emissive displays may utilize the benefits associated with blue light emitting μLEDs and red light emitting μOLEDs.

In some examples, the blue light emitting μLED subpixels may emit a bright blue color. As a result, the blue light emitting μLED subpixels may be shared by multiple pixels through use of rendering techniques. In addition, the size of the blue light emitting μLED may be increased, which may improve the efficiency and may reduce the number of transfers used in the fabrication of the hybrid emissive displays disclosed herein.

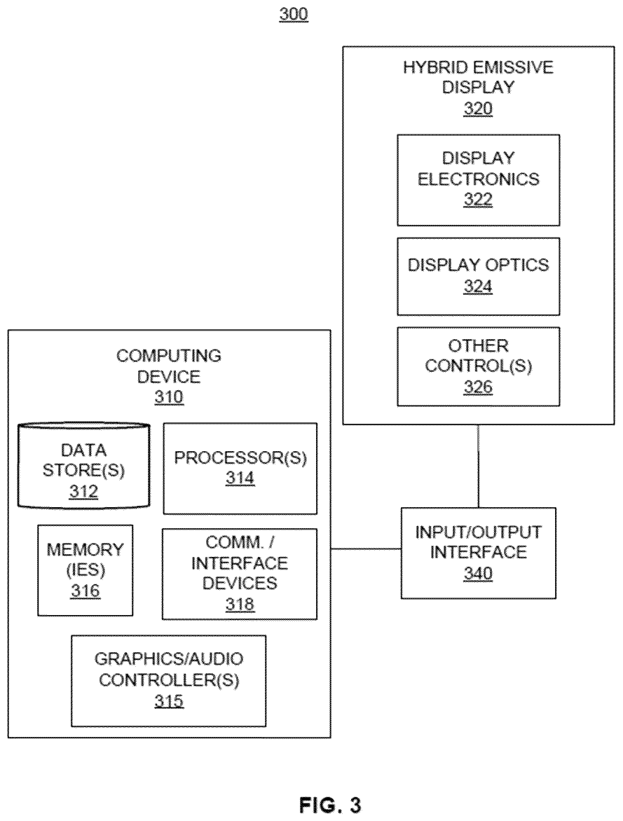

FIG. 3 illustrates a block diagram of a system environment 300 that includes a computing device 310 with a hybrid emissive display 320, according to an example. As used herein, the hybrid emissive display 320 may refer to a device that presents content (e.g., video, still images, three-dimensional images, etc.) through images of the content. The hybrid emissive display 320 may also include pixels formed of both μOLED and μLED subpixels. Such hybrid emissive displays 320 may include use of technologies associated with virtual reality (VR), augmented reality (AR), and/or mixed reality (MR). As used herein a “user” may refer to a user observing a display or wearer of a wearable hybrid emissive display 320.

As shown in FIG. 3, the system environment 300 may include a computing device 310, a hybrid emissive display 320, and an input/output interface 340 coupled between the computing device 310 and the hybrid emissive display 320 to enable communication and data exchange between the computing device 310 and the hybrid emissive display 320. The computing device 310 may include a number of components and sub-systems such as data storage(s) 312, processor(s) 314, memory(ies) 316, communication/interface devices 318, and graphics/audio controller(s) 315, among others. The hybrid emissive display 320 may include display electronics 322, display optics 324, and other control(s) 326, among other things. In some examples, part or all of the computing device 310 may be integrated with the hybrid emissive display 320.

In some instances, the computing device 310 may be any device capable of providing content to the hybrid emissive display 320 including, but not limited to, a desktop computer, a laptop computer, a portable computer, a wearable computer, a smart television, a server, a game console, a communication device, a monitoring device, or comparable devices. The computing device 310 may execute one or more applications, some of which may be associated with providing content to be displayed to the hybrid emissive display 320. The applications (and other software) may be stored in data storage(s) 312 and/or memory(ies) 316 and executed by processor(s) 314. Communication/interface devices 318 may be used to receive input from other devices and/or human beings, and to provide output (e.g., instructions, data) to other devices such as the hybrid emissive display 320. Graphics/audio controller(s) 315 may be used to process visual and audio data to be provided to output devices. For example, video or still images may be processed and provided to the hybrid emissive display 320 through the graphics/audio controller(s) 315.

In some examples, the data store(s) 312 (and/or the memory(ies) 316) may include a non-transitory computer-readable storage medium storing instructions executable by the processor(s) 314. The processor(s) 314 may include multiple processing units executing instructions in parallel. The non-transitory computer-readable storage medium may be any memory, such as a hard disk drive, a removable memory, or a solid-state drive (e.g., flash memory or dynamic random access memory (DRAM)). In some examples, the modules of the computing device 310 described in conjunction with FIG. 1 may be encoded as instructions in the non-transitory computer-readable storage medium that, when executed by the processor(s) 314, may cause the processor(s) 314 to perform the functions further described below.

In some examples, the data store(s) 312 may store one or more applications for execution by the computing device 310. An application may include a group of instructions that, when executed by the processor(s) 314, generates content for presentation to the user. Examples of the applications may include gaming applications, conferencing applications, video playback application, or other suitable applications.

In some examples, the hybrid emissive display 320 may be used to display content provided by the computing device 310 and may take any of many different shapes or forms. For example, the hybrid emissive display 320 may be a desktop monitor, a wall-mount monitor, a portable monitor, a wearable monitor (e.g., VR or AR glasses), and comparable ones to name a few.

In some examples, the computing device 310 may provide content to the hybrid emissive display 320 through the input/output interface 340. The input/output interface 340 may facilitate data exchange between the computing device 310 and the hybrid emissive display 320 through a wired or wireless connection (e.g., through radio frequency waves or optical waves) and include circuitry/devices to process exchanged data. For example, the input/output interface 340 may condition, transform, amplify, or filter signals exchanged between the computing device 310 and the hybrid emissive display 320. The computing device 310 and/or the hybrid emissive display 320 may include different or additional modules than those described in conjunction with FIG. 3. Functions further described herein may be distributed among components of the computing device 310 and the hybrid emissive display 320 in a different manner than as described here.

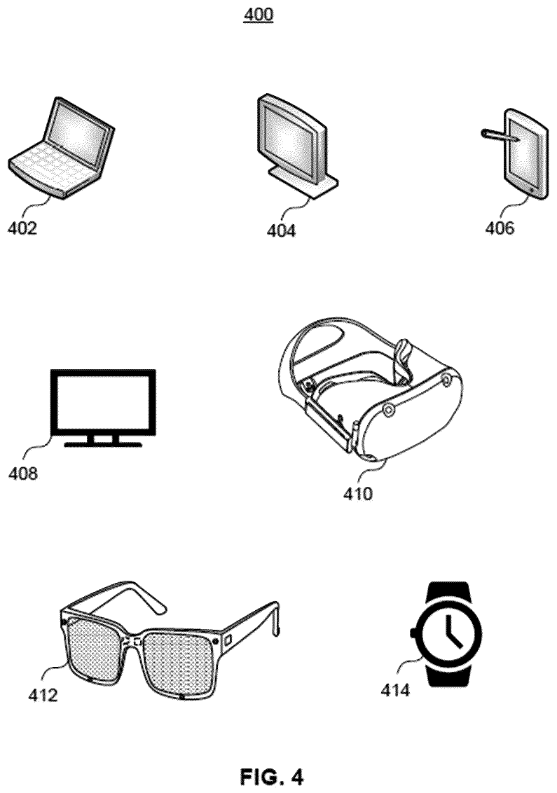

In some examples, the hybrid emissive display 320 may be implemented in any suitable form-factor as mentioned above, including a head-mounted display, a pair of glasses, or other similar wearable eyewear or device. Examples of the hybrid emissive display 320 are further described below with respect to FIG. 4. Additionally, in some examples, the functionality described herein may be used in a head-mounted display or headset that may combine images of an environment external to the hybrid emissive display 320 and artificial reality content (e.g., computer-generated images). Therefore, in some examples, the hybrid emissive display 320 may augment images of a physical, real-world environment external to the hybrid emissive display 320 with generated and/or overlaid digital content (e.g., images, video, sound, etc.) to present an augmented reality to a user.

In some examples, the display electronics 322 may display or facilitate the display of images to the user according to data received from, for example, the computing device 310. In some examples, the display electronics 322 may include one or more display panels. In some examples, the display electronics 322 may include any number of pixels to emit light of a predominant color such as red, green, blue, white, or yellow. In some examples, the display electronics 322 may display a three-dimensional (3D) image, e.g., using stereoscopic effects produced by two-dimensional panels, to create a subjective perception of image depth.

In some examples, the display electronics 322 may include circuitry to provide power to the pixels, control behavior of the pixels, etc. Control circuitry, also referred to as “drivers” or “driving circuitry”, may control which pixels are activated, illumination levels of the pixels, a desired gray level for each pixel in some examples, and/or the like.

In some examples, the display optics 324 may display image content optically (e.g., using optical waveguides and/or couplers) or magnify image light received from the display electronics 322, correct optical errors associated with the image light, and/or present the corrected image light to a user of the hybrid emissive display 320. In some examples, the display optics 324 may include a single optical element or any number of combinations of various optical elements as well as mechanical couplings to maintain relative spacing and orientation of the optical elements in the combination. In some examples, one or more optical elements in the display optics 324 may have an optical coating, such as an anti-reflective coating, a reflective coating, a filtering coating, and/or a combination of different optical coatings.

In some examples, the hybrid emissive display 320 may include additional modules and/or functionality such as audio output, image capture, location/position sensing, etc. Other control(s) 326 may be employed to control such functionality (e.g., level and/or quality of audio output, image capture, location/position sensing, etc.), as well as functionality of the hybrid emissive display 320 such as wireless remote control of the hybrid emissive display 320.

FIG. 4 illustrates a diagram 400 of various display devices in which the hybrid emissive display 320 depicted in FIG. 3 may be implemented, according to examples. In some examples, the hybrid emissive display 320 of FIG. 3 may be integrated with or communicatively coupled to a device such as laptop computer 402, desktop monitor 404, portable computer 406 (e.g., a tablet), wall-mounted display 408, head-mount display 410, glasses 412, or smart watch 414.

In some examples, the hybrid emissive display 320 may be a part of a VR system, an augmented reality (AR) system, a mixed reality (MR) system, another system that uses displays or wearables, or any combination thereof.

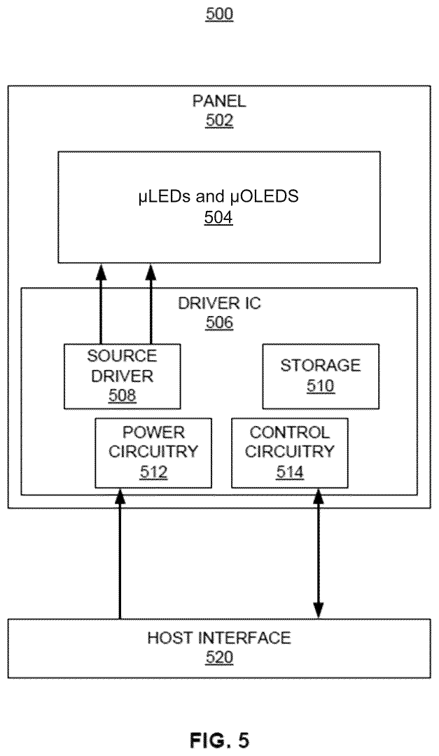

FIG. 5 is a block diagram of a hybrid emissive display 500, according to an example. In some examples, the hybrid emissive display 500 may be a specific implementation of the hybrid emissive display 320 of FIG. 3 and may be configured to operate as a VR display, an AR display, and/or a MR display.

As shown, the hybrid emissive display 500 may include a panel 502 containing μLEDs and μOLEDs 504 and a driver integrated circuit (IC) 506. In some examples, the hybrid emissive display 500 may be configured to present media or other content to a user through controlled activation and emission of the μLEDs and OLEDs 504. In some examples, the driver IC 506 may include electronics to perform functionality similar to those described with respect to FIGS. 3-4. The driver IC 506 may include, for example, a source driver 508, power circuitry 512, and control circuitry 514. The panel 502 may be communicatively coupled (wired or wirelessly) to a host interface 520. In some examples, the hybrid emissive display 500 may also include any number of optical components, such as waveguides, gratings, lenses, mirrors, etc.

In some examples, the source driver 508 may activate and control an illumination level, e.g., a gray level, of each subpixel (the μLEDs and the μOLEDs 504) of the panel 502 using digital driving, e.g., digital gray control. The driver IC 506 may include data storage components 510 such as registers, flash memory, etc. The driver IC 506 may also include power circuitry 512 to provide various supply and reference voltages, currents to the other circuitry in the driver IC 506. The driver IC 506 may further include control circuitry 514 such as clock generators, comparators, and similar circuits to control functionality of the remaining components. In an example operation, the power circuitry 512 may receive power through the host interface 520 and generate needed voltages and currents. Similarly, the control circuitry 514 may receive instruction signals and data through the host interface 520 and control functionality of the various components within the driver IC 506.

In some examples, digital drive control may be achieved through series-in and parallel-out data shift registers in columns and bit-weighted frequency clock lines and a local comparator (all in the driver IC 506) for each pixel. As the digital drive control allows use of advanced CMOS node, leveraging speed and smaller layout of advanced CMOS processes, source drivers may be implemented on a single IC using the same CMOS structure as the remaining circuitry. Furthermore, an output from driver IC 506 may be directly used in the backplane without a DAC.

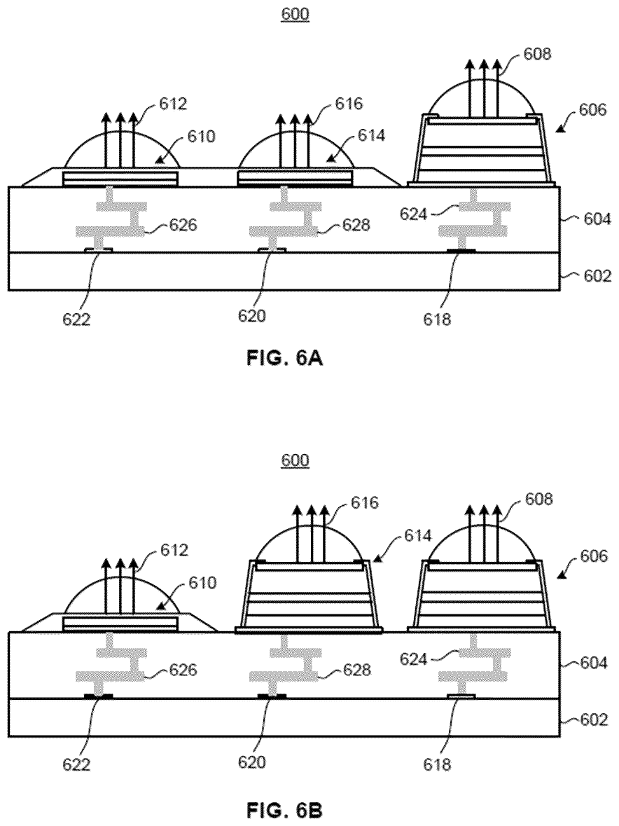

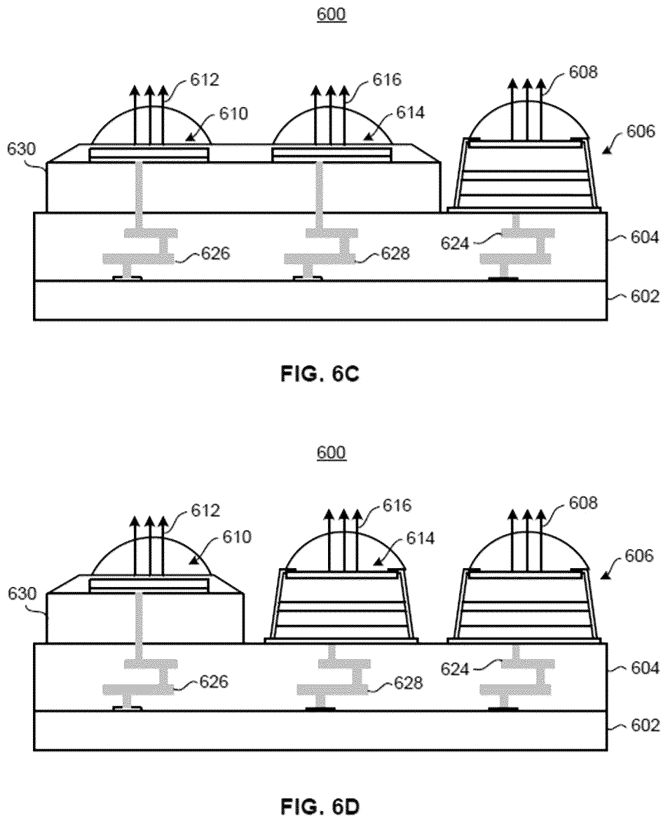

FIG. 6A illustrates a cross-sectional front view of a portion 600 of a hybrid emissive display, according to an example. The portion 600 may be a pixel 600 of the hybrid emissive displays 320, 500 shown in FIGS. 3 and 5 and the hybrid emissive displays 320, 500 may include a number of the pixels 600 arranged in an array. For instance, the hybrid emissive displays 320, 500 may include millions of the pixels 600 to provide, for example, 1080p resolution, 4K resolution, or the like.

As shown in FIG. 6A, each of the pixels 600 may include a substrate 602 and a backplane 604 formed on the substrate 602. The substrate 602 may be formed of silicon (Si), for instance. The backplane 604 may be a CMOS backplane. The pixels 600 may also include a first subpixel 606 positioned on the backplane 604, in which the first subpixel 606 is a μLED. The first subpixel 606 may be a μLED that is to emit a blue color light as represented by the arrows 608. The pixels 600 may further include a second subpixel 610 positioned on the backplane 604, in which the second subpixel 610 is a μOLED. The second subpixel 610 may be a μOLED that is to emit a red color light as represented by the arrows 612. The pixels 600 may still further include a third subpixel 614 positioned on the backplane 604, which is to emit a green color light as represented by the arrows 616.

As also shown in FIG. 6A, respective transistors 618-622 and sets of metal interconnects 624-628 may be formed in the backplane 604. The transistors 618-622 and the metal interconnects 624-628 may provide conductive pathways through which voltage may be applied to the respective subpixels 606, 610, 614. For instance, and with reference to FIG. 5, the source driver 508 of the driver IC 506 may drive voltage to the subpixels 606, 610, 614 through the transistors 618-622 and the metal interconnects 624-628. As discussed herein, the driver IC 506, the transistors 618-622, and the metal interconnects 624-628 may be part of digital driving components of the hybrid emissive display 320, 500 that may digitally drive the first subpixel 606, the second subpixel 610, and the third subpixel 614.

The digital driving components may simultaneously drive the subpixels 606, 610, 614 even though at least one of the subpixels 606 is a μLED and at least another one of the subpixels 610 is a μOLED. Particularly, for instance, the digital driving components may utilize pulse width modulation (PWM) to drive the μLED and μOLED subpixels 606, 610, 614. This may enable the subpixels 606, 610, 614 to be driven simultaneously through the metal interconnects 624-628, e.g., traces, formed in the common backplane 604. In some examples, different power domains with dedicated voltage settings (VDD, VSS, VRESET) may be used for the subpixels 606, 610, 614 depending upon whether the subpixels 606, 610, 614 are μLEDs or μOLEDs.

Accordingly, for instance, a first conductive trace, e.g., metal interconnect 624, may be connected to the first subpixel 606, which may be a μLED. In addition, a second conductive trace, e.g., metal interconnect 626, may be connected to the second subpixel 610, which may be a OLED. In these examples, a first voltage may be applied to the first subpixel 606 through the first conductive trace 624 and a second voltage may be applied to the second subpixel 610 through the second conductive trace 626. The first voltage may be tuned for driving μLEDs and the second voltage may be tuned for driving μOLEDs. As a result, the first voltage may differ from the second voltage.

According to examples, each of the subpixels 606, 610, 614 may be driven to simultaneously emit light at respective illumination levels to thus cause the pixel 600 in which the subpixels 606, 610, 614 are provided to emit a certain color of light. That is, each of the pixels 600 in the hybrid emissive display 320, 500 may emit a color of a relatively large number of colors through selective driving of the subpixels 606, 610, 614. The various colors emitted by the pixels 600 may form images and/or videos that a user may view.

In some examples, and as illustrated in FIG. 6A, the third subpixel 614 may be a μOLED and may thus be driven in similar manners as the second subpixel 610. In other examples, and as illustrated in FIG. 6B, the third subpixel 614 may be a μLED and may thus be driven in similar manners as the first subpixel 606.

In some examples, and as illustrated in FIGS. 6C and 6D, a planarization layer 630, such as an organic planarization layer 630, may be built on the backplane 604. In the example shown in FIG. 6C, in which the third subpixel 614 may be a μOLED, the metal interconnects 626 and 628 may be formed to extend through the planarization layer 630. In addition, the second subpixel 610 and the third subpixel 614 may be fabricated on the planarization layer 630 to electrically connect to the metal interconnects 626 and 628. The planarization layer 630 may raise the second subpixel 610 and the third subpixel 614 to a level that may be equivalent to the height of the first subpixel 606.

In the example shown in FIG. 6D, in which the third subpixel 614 may be a μLED, the metal interconnect 626 may be formed to extend through the planarization layer 630. In addition, the second subpixel 610 may be fabricated on the planarization layer 630 to electrically connect to the metal interconnect 626. The planarization layer 630 may raise the second subpixel 610 to a level that may be equivalent to the height of the first subpixel 606.

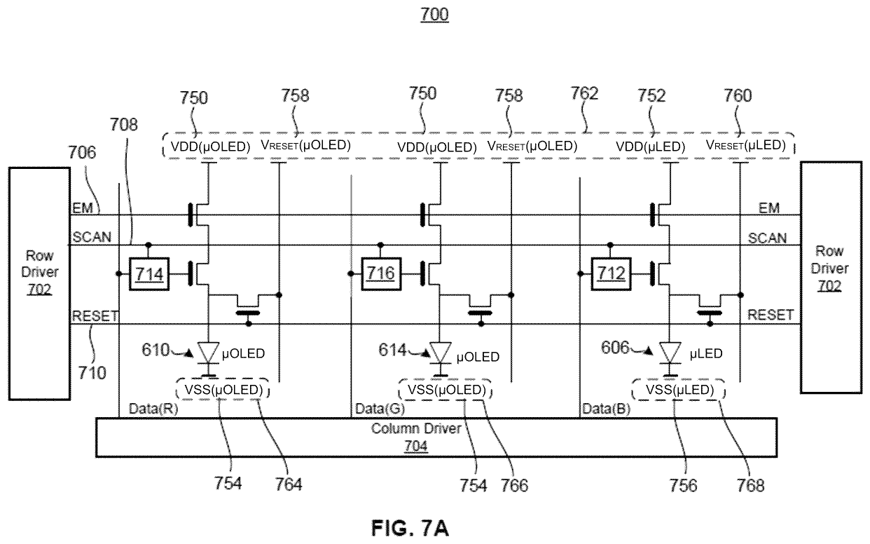

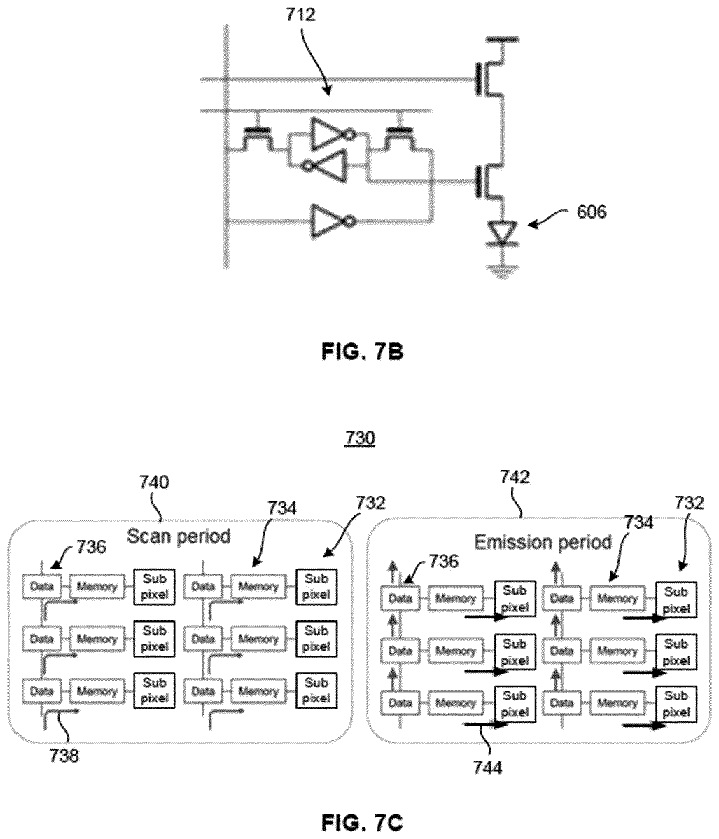

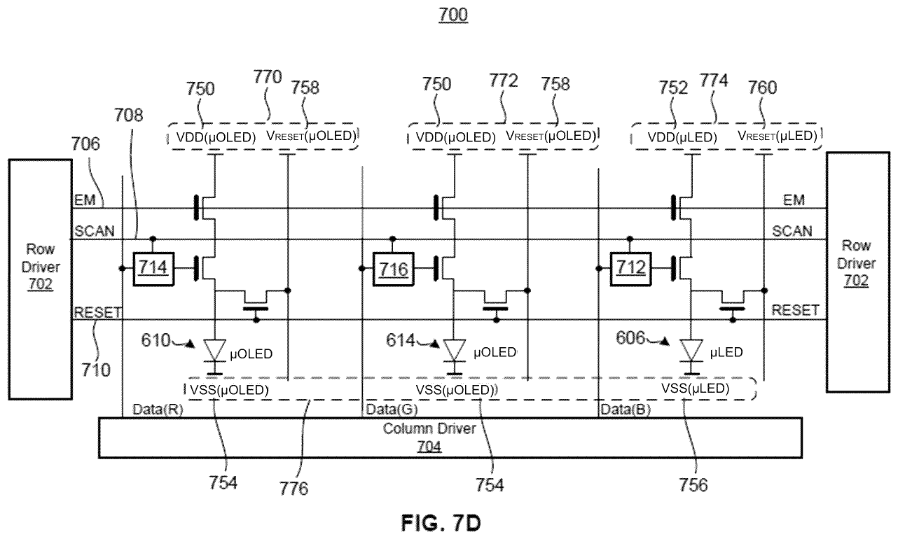

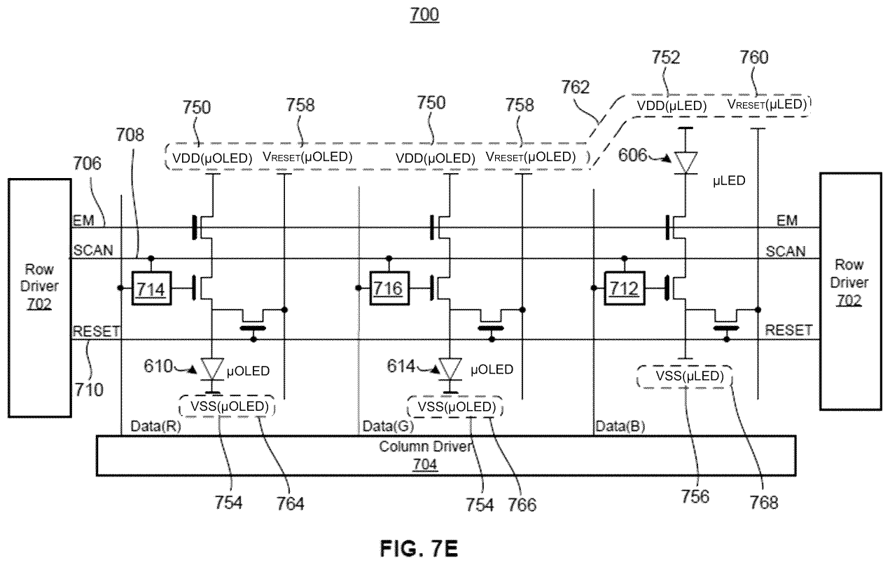

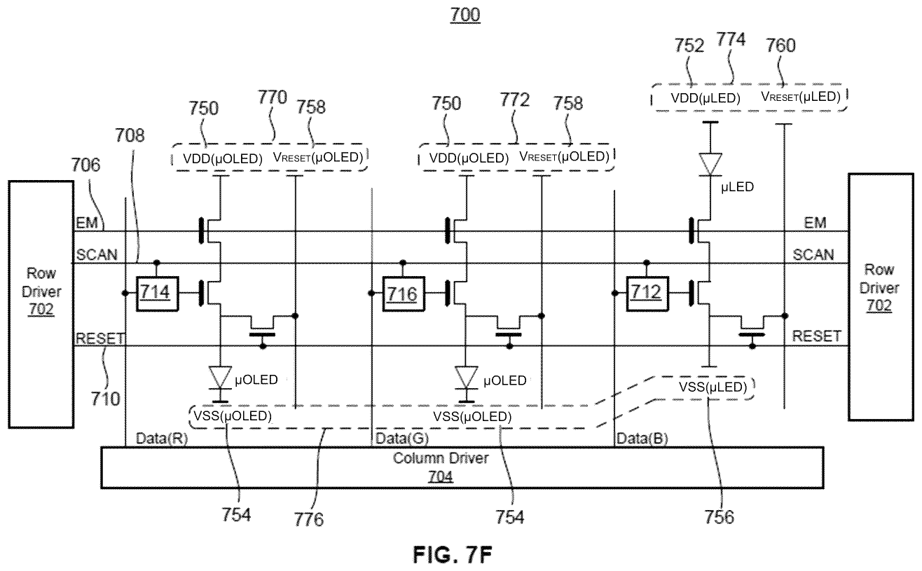

FIG. 7A illustrates a schematic diagram of digital driving components 700 for a pixel 600 having both μLED and μOLED subpixels 606, 610, 614, according to an example. The digital driving components 700 may include a row driver 702 and a column driver 704. The row driver 702 and the column driver 704 may be circuits and an emission line 706, a scan line 708, and a reset line 710 may be connected to the row driver 702 and the column driver 704. The row driver 702 and the column driver 704 may selectively apply voltages across the lines 706-710 to selectively cause the subpixels 606, 610, 614 to become illuminated.

As shown in FIG. 7A, each of the subpixels 606, 610, 614 is connected to a respective memory 712-716. The memories 712-716 may be any suitable types of memory circuits, memory blocks, static random access memory (SRAM), or the like. By way of example, the memories 712-716 may be any type of cache that may temporarily store a bit of information. A non-limiting example of a suitable memory circuit 712 is illustrated in FIG. 7B.

FIG. 7C illustrates diagrams 730 of operations of a matrix of subpixels 732 that include memories 734, according to an example. In FIG. 7C, the subpixels 732 may correspond to the subpixels in a hybrid emissive display 320, 500, including the subpixels 606, 610, 614 depicted in FIG. 7A. In addition, the memories 734 may correspond to the memories 712, 714, 716. As shown in FIG. 7C, the diagrams 730 include a scan period diagram 740 and an emission period diagram 742.

As shown in the scan period diagram 740, data 736 may be written into the memories 734. Particularly, for instance, the column driver 704 may deliver the data 736 to a first subpixel 732 and the first subpixel 732 may pass the data 736 to a next subpixel 732. After one subframe period (for a 4K panel, after 4K clocks), each subpixel 732 may have its designated data 736 written in its memory 734. This approach may enable all of the subpixels 732 to write the data 736 into the memories 734 simultaneously. Therefore, a panel may show an image with a page by page, e.g., panel 502 shown in FIG. 5, of subframes.

The subpixels 732 in one line may be connected in series and may be in the vertical or horizontal direction. A subblock of a subpixel data array is placed for each of the subpixels 732. With one clock cycle (or half clock cycle or multiple cycles), the data 736 may move in a one-pixel step. In addition, the data 736 may be moved across the panel 502 until the first data reaches the last subpixel in a line. While the data 736 is transferring, the panel 502 may be in the emission phase, and the data movement may not affect the pixel emission. In the scan and write phase, the data 736 may be written to and held in the memories 734 of the subpixels 732.

As shown in the emission period diagram 742, in the next emission phase, the subpixels 732 may be turned-on or off based on the data 736 held in the respective memories 734, as denoted by the arrows 744. In some examples, the data 736 may include clock information of the subpixels 732, such as the durations of time that the subpixels 732 are to be activated, which may control the illumination levels of the subpixels 732. The data 736 may be driven to the memories 734 through pulse width modulation (PWM) and thus, the subpixels 732 may be driven digitally. Examples disclosed herein may be directed to driving the data 736 such that a pulse width of the applied voltage may be varied, as opposed to amplitude, to generate the desired illumination level in the activated subpixels 732.

In some examples, reset voltages may be applied to the memories 712-716 between each successive data write operation. The reset voltages may clear the memories 712-716 such that the memories 712-716 may receive new data during each new data write operation. In other words, a reset voltage source may apply a reset voltage on a reset line to reset anodes of the first subpixel 606, the second subpixel 610, and the third subpixel 614 between activation cycles.

With reference back to FIG. 7A, the digital driving components 700 are depicted as including μOLED subpixel supply voltages (VDD(μOLED)) 750 and a μLED subpixel supply voltage (VDD(LED)) 752. The digital driving components 700 are also depicted as including OLED subpixel drain voltages (VSS(μOLED)) 754 and a μLED subpixel drain voltage (VSS(μLED)) 756. The digital driving components 700 is further depicted as including a μOLED reset voltage (VRESET(μOLED)) 758 and a μLED reset voltage (VRESET(μLED)) 760.

In some examples, the μOLED subpixels 610, 614 and the μLED subpixels 606 may have different current-voltage-luminance characteristics and may thus require different voltage biases. The backplane 604 of the hybrid emissive display 320, 500 may address this different voltage bias requirement by including two different power domains. For instance, the backplane 604 may include a first dedicated set of voltage settings (VSS, VDD, and VRESET) for the μOLED subpixels 610, 614 and a second dedicated set of voltage settings (VSS, VDD, and VRESET) for the μLED subpixel 606. The voltage settings for the μOLED subpixels 610, 614 may thus differ from the voltage settings for the μLED subpixel 606. In addition, the row driver 702 may have a different signal or clock line for the μOLED subpixels 610, 614 and the μLED subpixel 606.

In FIG. 7A, the μOLED subpixels 610, 614 and the μLED subpixel 606 may be in the same source VDD and VRESET domains. This shared domain is denoted by the dashed box 762. In addition, the drain VSS domains for the μOLED subpixels 610, 614 and the μLED subpixel 606 may differ from each other. The different drain VSS domains are denoted by the dashed boxes 764-768. In some examples, the drain VSS domains 764 and 766 may be combined into a single domain.

In other examples, and as illustrated in FIG. 7D, the μOLED subpixels 610, 614, and the μLED subpixel 606 may be in separate source VDD and VRESET domains. The separate domains are denoted by the dashed boxes 770-774. In some examples, the source VDD and VRESET domains for the μOLED subpixels 610, 614 may be combined into a single domain. In addition, the μOLED subpixels 610, 614 and the μLED subpixels 606 may share a common domain as denoted by the dashed box 776.

The digital driving components 700 illustrated in FIGS. 7A and 7D may be directed to a pixel 600 having a first μLED subpixel 606 (e.g., blue color light emitting μLED), a second μOLED subpixel 610 (e.g., a red color light emitting μOLED), and a third μOLED subpixel 614 (e.g., a green color light emitting μOLED). In other examples, instead of being a μOLED, the third subpixel 614 may be a μLED. In those examples, the voltage settings for the third subpixel 614 may be equivalent to the voltage settings for the first subpixel 606.

In FIGS. 6A-6D, 7A, and 7D, the first μLED subpixel 606 is illustrated as being positioned such that the P side of the μLED subpixel 606 (e.g., the p-GaN layer of the μLED subpixel 606) is facing away from the backplane 604. In other examples, and as illustrated in FIGS. 7E and 7F, the first μLED subpixel 606 may be positioned on the backplane 604 such that the N side of the μLED subpixel 606 (e.g., n-GaN layer of the μLED subpixel 606) faces away from the backplane 604.

Other than the orientation of the first μLED subpixel 606, the digital driving components 700 depicted in FIG. 7E are similar to digital driving components 700 depicted in FIG. 7A. That is, the μOLED subpixels 610, 614 and the μLED subpixel 606 may be in the same source VDD and VRESET domains, while the drain VSS domains for the μOLED subpixels 610, 614 and the μLED subpixel 606 may differ from each other.

In addition, other than the orientation of the first μLED subpixel 606, the digital driving components 700 depicted in FIG. 7F are similar to the digital driving components 700 depicted in FIG. 7D. That is, in FIG. 7F, the μOLED subpixels 610, 614, and the μLED subpixel 606 may be in separate source VDD and VRESET domains. The separate domains are denoted by the dashed boxes 770-774. In some examples, the source VDD and VRESET domains for the μOLED subpixels 610, 614 may be combined into a single domain. In addition, the μOLED subpixels 610, 614 and the μLED subpixels 606 may share a common domain as denoted by the dashed box 776.

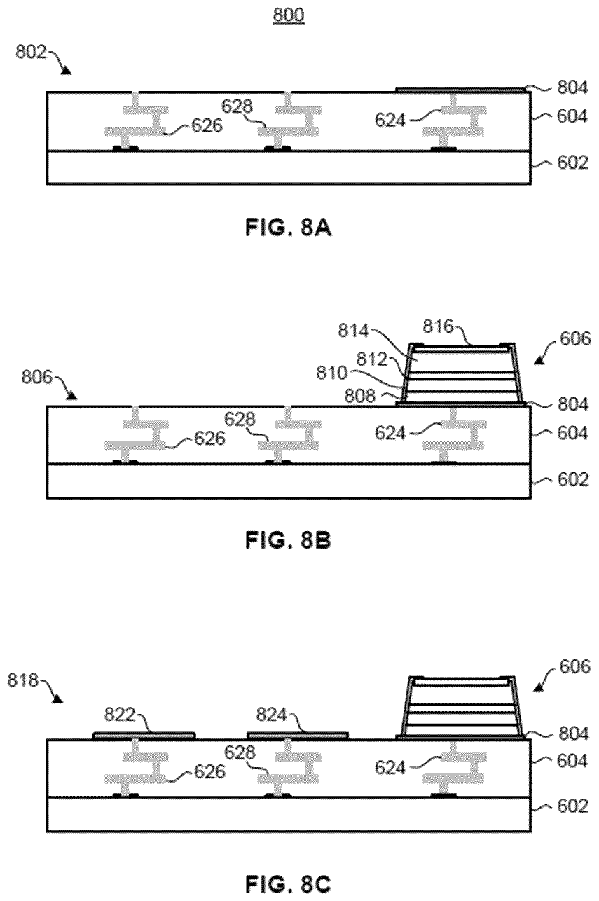

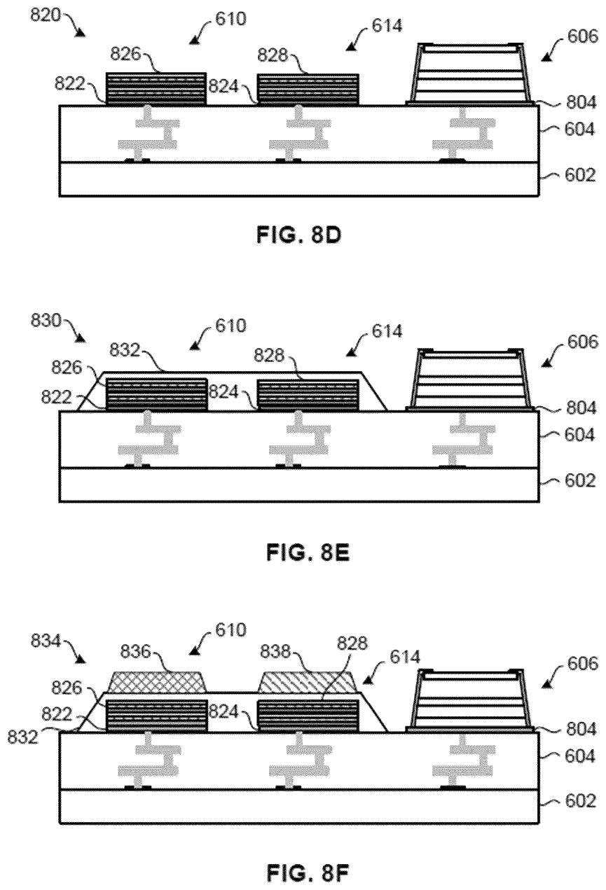

FIGS. 8A-8F, collectively, illustrate operations in a method 800 of fabricating a hybrid emissive display, according to an example. The hybrid emissive display fabricated using the method 800 may include any of the hybrid emissive displays 320, 500 discussed herein. The descriptions of FIGS. 8A-8F are made with respect to the features shown in FIGS. 6A-6D for purposes of illustration.

As shown in FIG. 8A, in an operation 802, a backplane 604 and a substrate 602 may be fabricated. In some examples, the substrate 602 may be formed of silicon and the backplane 604 may be a CMOS backplane. In some examples, the substrate 602 may form part of the CMOS backplane 604. In any of these examples, the substrate 602 and the backplane 604 may be fabricated through any suitable fabrication process to include the formation of the metal interconnects 624-628. In other words, the backplane 604 may be fabricated to include traces (metal interconnects 624-628) for conduction of electrical current through the backplane 604. For instance, the backplane 604 may be fabricated to include the traces and the digital driving components 700 depicted in FIG. 7A or 7D. Thus, the backplane 604 may include the row driver 702, the column driver 704, the memories 712-716, etc.

In addition, a μLED bottom electrode 804 may be deposited and patterned on the backplane 604 to be in electrical contact with the metal interconnect 624. The μLED bottom electrode 804 may be fabricated through a deposition and patterning process. As shown in FIG. 8B, in an operation 806, a first subpixel 606, e.g., a μLED that is to emit a blue color light, may be placed on the μLED bottom electrode 804.

In the example shown in FIG. 8B, the first subpixel 606 may include a GaN buffer layer 808 in contact with the μLED bottom electrode 804. The first subpixel 606 may also include an n-GaN layer 810, an emitter layer 812 (which may be a multiple-quantum well), a p-GaN layer 814, and an anode 816 (which may be formed of indium tin oxide (ITO)). In this regard, the first subpixel 606 may be positioned on the μLED bottom electrode 804 such that the P side of the first subpixel 606, and thus, the anode 816, faces away from the backplane 604.

According to examples, the first subpixel 606 may be prefabricated prior to placement of the first subpixel 606 on the μLED bottom electrode 804. That is, the first subpixel 606 may be prefabricated and the prefabricated first subpixel 606 may be moved onto the μLED bottom electrode 804. The prefabricated first subpixel 606 may be transferred to the LED bottom electrode 804 and thus onto the backplane 604 through any suitable transfer process. For instance, a plurality of prefabricated first subpixels 606 may be mass transferred onto the backplane 604 through an elastomer stamp/adhesive process, through use of an electrostatic pick and place process, through use of a mass transfer tool manipulator assembly, through use of a laser-based transfer process, through use of a fluidic-based assembly transfer process, through use of a roll-to-roll transfer process, and/or the like.

Following placement of the first subpixel 606 (μLED) onto the μLED bottom electrode 804, a high temperature annealing process may be employed to secure the bonding of the first subpixel 606 to the μLED bottom electrode 804 and passivate defects.

As illustrated in FIGS. 8C and 8D, in operations 818 and 820, a second subpixel 610 may be fabricated on the backplane 604 following placement of the prefabricated first subpixel 606 on the μLED bottom electrode 804. Particularly, the second subpixel 610 may be fabricated following placement and bonding of the prefabricated first subpixel 606 to the μLED bottom electrode 804. According to examples, the second subpixel 610 (and the third subpixel 614) may be fabricated following the application of heat to bond the prefabricated first subpixel 606 to the μLED bottom electrode 804. As a result, the layers forming the second subpixel 610 (and the third subpixel 614) may not need to withstand that heat, which may otherwise damage the layers.

In the operation 818 illustrated in FIG. 8C, a second subpixel electrode 822 may be formed on the backplane 604. In addition, a third subpixel electrode 824 may be formed on the backplane 604. In some examples, the second subpixel electrode 822 and the third subpixel electrode 824 may each include an aluminum (AL) reflector and anode ITO electrode. The second subpixel electrode 822 and the third subpixel electrode 824 may be formed through selective deposition of materials onto the backplane 604.

In the operation 820 illustrated in FIG. 8D, the second subpixel 610, e.g., μOLED layers 826 forming the second subpixel 610, may be formed on the second subpixel electrode 822. In addition, the third subpixel 614, e.g., μOLED layers 828 forming the third subpixel 614, may be formed on the third subpixel electrode 824. The μOLED layers 826, 828 forming the second subpixel 610 and the third subpixel 614 may be formed through deposition of the layers, such as by forming the μOLED emitter layers 826, 828 through an evaporation process.

As illustrated in FIG. 8E, in an operation 830, an encapsulation layer 832 may be deposited over the μOLED layers 826, 828. The encapsulation layer 832 may be an atomic layer deposition (ALD) thin film, for instance.

As illustrated in FIG. 8F, in an operation 834, a color filter 836 may be deposited onto the encapsulation layer 832 over the μOLED layers 826 of the second subpixel 610. The color filter 836 may be, for instance a red color filter such that when the μOLED layers 826 are activated to emit light, the emitted light may have a red color. In addition, a color filter 838 may be deposited onto the encapsulation layer 832 over the μOLED layers 828 of the third subpixel 614. The color filter 838 may be, for instance a green color filter such that when the μOLED layers 826 are activated to emit light, the emitted light may have a green color.

In some examples, prior to, during, or after deposition of the color filters 836, 838, excess materials that may have been deposited onto the first subpixel 606 may be removed.

According to examples, a planarization layer 630 may be formed on the backplane 604 as shown in FIGS. 6C and 6D. Particularly, for instance, the planarization layer 630 may be formed of an organic material and may be fabricated in a manner similar to the manner in which the backplane 604 is fabricated. In some examples, the planarization layer 630 may be formed following the operation 806 depicted in FIG. 8B. In other words, the planarization layer 630 may be fabricated following the placement and bonding of the first subpixel 606 onto the μLED bottom electrode 804.

The planarization layer 630 may also be fabricated to extend the metal interconnects 626, 628 from the backplane 604 to an upper surface of the planarization layer 630. The planarization layer 630 may be sized to cause the second subpixel 610 (and the third subpixel 614) to be at a substantially similar height as the first subpixel 606. In some examples, the planarization layer 630 may be fabricated following placement and bonding of the first subpixel 606 and thus, the planarization layer 630 may avoid potential damage caused by the heat applied during the bonding of the first subpixel 606 to the μLED bottom electrode 804.

In addition, in the operation 818, the second subpixel electrode 822 and the third subpixel electrode 824 may be formed on top of the planarization layer 630 to be in electrical contact with the respective metal interconnects 626, 628. The second subpixel 610 and the third subpixel 614 may be formed on the electrodes 822, 824 as discussed herein.

According to examples, instead of being a μOLED, the third subpixel 614 may be a μLED. In these examples, in operation 802, a second μLED bottom electrode (not shown) may be formed with the μLED bottom electrode 804. In addition, the third μLED subpixel 614 may be placed onto and bonded to the second μLED bottom electrode. Examples of this configuration are shown in FIGS. 6B and 6D. The second subpixel 610 may be formed in the manners discussed herein.

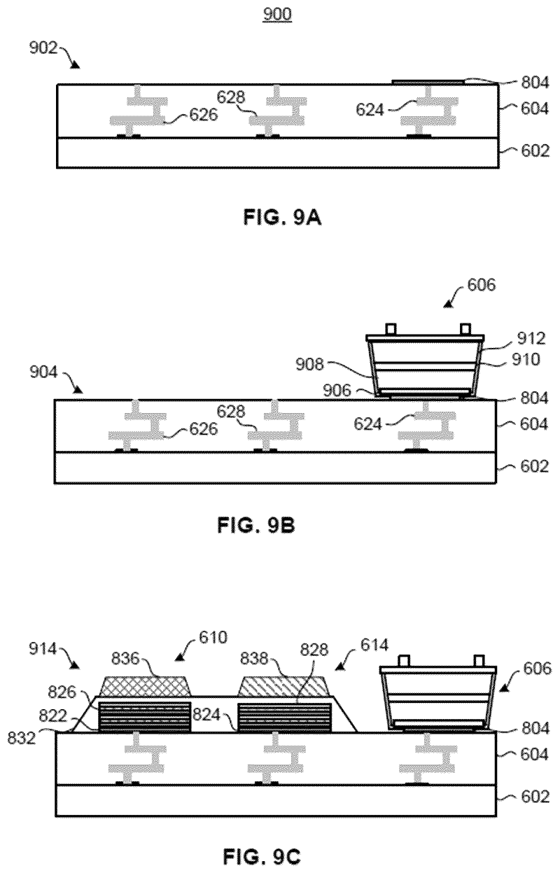

FIGS. 9A-9C, collectively, illustrate operations in a method 900 of fabricating a hybrid emissive display, according to an example. The hybrid emissive display fabricated through the method 900 may include any of the hybrid emissive displays 320, 500 discussed herein. The descriptions of FIGS. 9A-9C are made with respect to the features shown in FIGS. 6A-6D for purposes of illustration. The method 900 differs from the method 800 in that the first subpixel 606 is positioned such that the N side of the μLED faces away from the backplane 604.

As shown in FIG. 9A, in an operation 902, a backplane 604 and a substrate 602 may be fabricated. A μLED bottom electrode 804 may also be fabricated on an upper surface of the backplane 604. The substrate 602, the backplane 604, and the μLED bottom electrode 804 may be fabricated in any of the manners discussed above with respect to FIG. 8A.

As shown in FIG. 9B, in an operation 904, a first subpixel 606, e.g., a μLED that is to emit a blue color light, may be placed on the μLED bottom electrode 804. In the example shown in FIG. 9B, the first subpixel 606 may include an anode 906 (which may be formed of indium tin oxide (ITO) that is in contact with the μLED bottom electrode 804. The first subpixel 606 may also include a p-GaN layer 908, an emitter layer 910 (which may be a multiple-quantum well), and an n-GaN layer 912. In this regard, the first subpixel 606 is positioned on the μLED bottom electrode 804 such that the N side of the first subpixel 606 faces away from the backplane 604. In some examples, the first subpixel 606 may be prefabricated and may be placed onto the μLED bottom electrode 804 in any of the manners discussed herein.

According to examples, the operations depicted in FIGS. 8C-8F may be implemented in the method 900 to result in the operation 914 shown in FIG. 9C. In addition, in some examples, a planarization layer 630 may be formed on the backplane 604 as discussed above with respect to the method 800.

In the foregoing description, various inventive examples are described, including devices, systems, methods, and the like. For the purposes of explanation, specific details are set forth in order to provide a thorough understanding of examples of the disclosure. However, it will be apparent that various examples may be practiced without these specific details. For example, devices, systems, structures, assemblies, methods, and other components may be shown as components in block diagram form in order not to obscure the examples in unnecessary detail. In other instances, well-known devices, processes, systems, structures, and techniques may be shown without necessary detail in order to avoid obscuring the examples.

The figures and description are not intended to be restrictive. The terms and expressions that have been employed in this disclosure are used as terms of description and not of limitation, and there is no intention in the use of such terms and expressions of excluding any equivalents of the features shown and described or portions thereof. The word “example” is used herein to mean “serving as an example, instance, or illustration.” Any embodiment or design described herein as “example” is not necessarily to be construed as preferred or advantageous over other embodiments or designs.

Although the methods and systems as described herein may be directed mainly to digital content, such as videos or interactive media, it should be appreciated that the methods and systems as described herein may be used for other types of content or scenarios as well. Other applications or uses of the methods and systems as described herein may also include social networking, marketing, content-based recommendation engines, and/or other types of knowledge or data-driven systems.

1. A hybrid emissive display, comprising:
a substrate;
a backplane formed on the substrate;
a first subpixel positioned on the backplane, the first subpixel being a micro light emitting diode (μLED);
a second subpixel positioned on the backplane, the second subpixel being a micro organic light emitting diode (μOLED);
a third subpixel positioned on the backplane, the third subpixel being a μOLED or a μLED; and
at least one digital driving component to digitally drive the first subpixel, the second subpixel, and the third subpixel.

2. The hybrid emissive display of claim 1, wherein the first subpixel is to emit a blue color light, the second subpixel is to emit a red color light, and the third subpixel is to emit a green color light.

3. The hybrid emissive display of claim 1, wherein the at least one digital driving component comprises:
a first conductive trace connected to the first subpixel, wherein a first voltage is to be applied to the first subpixel through the first conductive trace; and
a second conductive trace connected to the second subpixel, wherein a second voltage is to be applied to the second subpixel through the second conductive trace.

4. The hybrid emissive display of claim 1, wherein the at least one digital driving component comprises:
a dedicated supply voltage source for the first subpixel and the second subpixel;
a first ground for the first subpixel; and
a second ground for the second subpixel.

5. The hybrid emissive display of claim 1, wherein the at least one digital driving component comprises:
a first supply voltage source for the first subpixel;
a second supply voltage source for the second subpixel; and
a dedicated ground for the first subpixel and the second subpixel.

6. The hybrid emissive display of claim 1, wherein the at least one digital driving component comprises a row driver and a column driver, wherein the row driver comprises a first signal or clock line for the first subpixel and a second signal or clock line for the second subpixel.

7. The hybrid emissive display of claim 1, wherein each of the first subpixel, the second subpixel, and the third subpixel comprises a respective memory that receives and stores data regarding durations at which the first subpixel, the second subpixel, and the third subpixel are to be activated during a next emission cycle.

8. The hybrid emissive display of claim 7, wherein the at least one digital driving component comprises a reset voltage source and a reset line to reset the memories of the first subpixel, the second subpixel, and the third subpixel between activation cycles.

9. The hybrid emissive display of claim 1, wherein the backplane comprises a complementary metal-oxide semiconductor backplane.

10. The hybrid emissive display of claim 1, wherein the first subpixel is formed separately from the second subpixel, and wherein the second subpixel is fabricated on the backplane following placement of the first subpixel on the backplane.

11. A method of fabricating a hybrid emissive display, comprising:
fabricating a backplane having traces for conduction of electrical current through the backplane;
depositing and patterning a micro light emitting diode (μLED) bottom electrode on a top surface of the backplane;
placing a prefabricated first subpixel on the μLED bottom electrode, wherein the prefabricated first subpixel is a μLED; and
fabricating a second subpixel on the backplane following placement of the prefabricated first subpixel on the μLED bottom electrode, wherein the second subpixel is a micro organic light emitting diode (μOLED).

12. The method of fabricating a hybrid emissive display of claim 11, further comprising:
fabricating a third subpixel on the backplane following placement of the prefabricated first subpixel on the μLED bottom electrode, wherein the third subpixel is a μOLED.

13. The method of fabricating a hybrid emissive display of claim 11, further comprising:
depositing a second μLED bottom electrode on the top surface of the backplane; and
placing a prefabricated third subpixel on the second μLED bottom electrode, wherein the prefabricated third subpixel is a μLED.

14. The method of fabricating a hybrid emissive display of claim 11, further comprising:
building a planarization layer of the backplane following placement of the prefabricated first subpixel; and
fabricating the second subpixel on the planarization layer of the backplane, wherein the planarization layer is to cause the second subpixel to be at a substantially similar height as the first subpixel.

15. The method of fabricating a hybrid emissive display of claim 11, wherein fabricating the backplane further comprises fabricating the backplane to include a first conductive trace to the μLED bottom electrode and a second conductive trace to a μLED bottom electrode, wherein first conductive trace is to receive a first voltage and the second conductive trace is to receive a second voltage.

16. The method of fabricating a hybrid emissive display of claim 11, wherein fabricating the second subpixel comprises fabricating the second subpixel to include a memory to receive and store data regarding durations at which the second subpixel is to be activated.

17. A hybrid emissive display, comprising:
a complementary metal-oxide semiconductor backplane;
a first subpixel positioned on the backplane, the first subpixel being a micro light emitting diode (μLED);
a second subpixel positioned on the backplane, the second subpixel being a micro organic light emitting diode (μOLED);
a third subpixel positioned on the backplane, the third subpixel being a μOLED or a μLED; and
at least one digital driving component having a first memory, a second memory, and a third memory, wherein the at least one digital driving component is to drive the first subpixel, the second subpixel, and the third subpixel through digital application of voltages to the first subpixel, the second subpixel, and the third subpixel.

18. The hybrid emissive display of claim 17, wherein the first subpixel is to emit a blue color light, the second subpixel is to emit a red color light, and the third subpixel is to emit a green color light.

19. The hybrid emissive display of claim 17, wherein the at least one digital driving component comprises:
a first conductive trace connected to the first subpixel, wherein a first voltage is to be applied to the first subpixel through the first conductive trace; and
a second conductive trace connected to the second subpixel, wherein a second voltage is to be applied to the second subpixel through the second conductive trace.

20. The hybrid emissive display of claim 17, wherein the at least one digital driving component comprises:
a first power domain to supply voltage at a first level to the first subpixel; and
a second power domain to supply voltage at a second level to the second subpixel.
